(19) United States
(12) Patent Application Publication
(10) Pub. No.: US 2004/0130034 A1
(43) Pub. Date: Jul. 8, 2004

(54) Method for forming a wafer level chip scale package

(75) Inventor: Romeo Emmanuel P. Alvarez, Singapore (SG)

Correspondence Address: GEORGE O. SAILE & ASSOCIATES, 28 DAVIS AVENUE, POUGHKEEPSIE, NY, 12603, US

(73) Assignee: Advanpack Solutions Pte Ltd.

(21) Appl. No.: 10/170,934

(22) Filed: Jun. 13, 2002

(30) Foreign Application Priority Data
Jun. 13, 2001 (SG) 200103485.9

(51) Int. Cl. H01L 23/02; H01L 21/44

(52) U.S. Cl. 257/762; 438/687; 257/766

(57) ABSTRACT

A layer of gold (405) is disposed on upper surfaces (225) of copper pillars (210) on a bumped wafer (205). Coating material (410) is then applied to a level which is less than the height of the copper pillars (210), and etchant is disposed to remove coating material on the layer of gold (405) and to remove coating material (410) adhering to side surfaces of the copper pillars (210). Solder deposits are then disposed on the gold layer and reflowed to form balls (405) on the ends of the copper pillars (210), with the copper pillars (210) protruding into the solder balls (405).

### FIELD OF THE INVENTION

The present invention relates to forming a wafer level chip scale package, and more particularly to forming a wafer level chip scale package that avoids mechanical grinding.

### BACKGROUND OF THE INVENTION

With a need for smaller semiconductor packages, there are now processes for packaging of semiconductor integrated circuits or dies at the wafer level. Such process are commonly and collectively referred to is as wafer level chip scale packaging, and the resultant package is referred to as a wafer level chip scale package (WL-CSP).

With reference to FIGS. 1 and 2A-E, an example of a wafer level chip scale packaging process 100 is now described. After components, circuitry and pads have been fabricated on a wafer 205 by processes as will be known to one skilled in the art, the packaging process 100 starts 105 with providing 110 the wafer 205 with metal pillars 210 formed on the die pads 212. FIG. 2A shows the wafer 205 with the metal pillars 210 formed on the die pads 212.

U.S. patent application Ser. No. 09/564,382 by Francisca Tung, filed on Apr. 27, 2000, titled “Improved Pillar Connections For Semiconductor Chips and Method Of Manufacture”, and Continuation-In-Part U.S. patent application Serial No. (Not yet assigned) by Francisca Tung, filed on Apr. 26, 2000 titled “Improved Pillar Connections For Semiconductor Chips aid Method Of Manufacture”, and assigned to a common assignee as this patent application, teaches forming at least some of such pillar structures as described herein. These patent applications are incorporated herein by reference.

A layer of coating material 215, such as mold compound, encapsulant epoxy, such as underfill coating material, or photo imageable material, such as benzocyclobutene (BCB) or polymide, is then applied 115 over the wafer 205, with the metal pillars 210 covered by the coating material 215, as shown in FIG. 2B. The layer of coating material 215 is applied with a spin coating process. Typically, two layers of material each with a thickness of about 40-50 micro-meters (μm) are applied to produce the resulting layer of coating material 215 with a thickness of about 100 μm. The coating material should be no more than 10 μm thick on the layer of gold 210. The layer of coating material 215 is then cured.

After curing, the excess coating material on the copper pillars 210 is ground 120 away using mechanical grinding by employing abrasive compounds on grinding machines, by Okamoto Corporation of USA or Kemet International Limited of the UK, and using a poromeric polishing pad. Grinding 120 continues until the excess coating material is removed and the upper surfaces 220 of the copper pillars 210 are exposed. The ground wafer is shown in FIG. 2C.

Next a layer of gold 225 is formed 125 on the upper surfaces 220 by, for example, electroplating, as shown in FIG. 2D; and solder balls 230 are attached 130 to the layer of gold 225. Equipment by manufacturers including OKI, Casio, Fujitsu, all of Japan can be used to attach the solder balls. The wafer level packaging process 100 then ends 135. After the process 100, the bumped wafer 235 is diced to singulate the WL-CSPs.

During the grinding step 120, the wafer 205 is subjected to severe mechanical stress, and can result in micro-cracks in the wafer. Hence, a disadvantage of the process of making WL-CSPs using mechanical grinding is the potential of adverse reliability caused by micro-cracks. Another disadvantage of mechanical grinding is that grinding is slow. Yet another disadvantage is the need to invest in grinding equipment and an associated supply of grinding consumables.

Etching is an alternative to grinding, where an etchant is applied to etch away the excess portion of the layer of coating material 215. However, etching is a slow process, and the relatively large volume of excess portion of the layer of coating material 215 that has to be removed further compounds the difficulties of using the etching process.

Since only the upper surfaces of the layer of gold are exposed, the surface area of the gold layer to which the solder balls 230 can adhere is limited. Hence, another disadvantage is the limited surface area of the gold to which the solder balls can adhere as this relates to adverse reliability of the WL-CSP.

The spin coating process is slow, and in addition, two spin coating operations are required to obtain a coating with the required thickness. In addition, the spin coating process wastes approximately 85% of the coating material that is disposed on the wafer 205. Therefore, still another disadvantage of the process described is the use of spin coating, which is both expensive and slow.

### BRIEF SUMMARY OF THE INVENTION

The present invention seeks to provide a method for forming a wafer level chip scale package and a package formed thereby, which overcomes or at least reduces the abovementioned problems of the prior art.

Accordingly, in one aspect, the present invention provides a method for forming a wafer level chip scale semiconductor package, the method comprising the steps of:

a) providing a semiconductor wafer having a surface with a plurality of pads, wherein each of the pads has a metallic conductor extending a first predetermined distance away from the surface;

b) forming a layer of conductive etch resistant material on free ends of the metallic conductors;

c) disposing electrically insulating material on the surface of the semiconductor wafer, wherein the layer of electrically insulating material has an exposed surface a second predetermined distance from the surface of the semiconductor wafer, wherein the second predetermined distance is less than the first predetermined distance, and wherein portions of the electrically insulating material are disposed on the layer of conductive etch resistant material and on side surfaces of at least some of the metallic conductors;

d) etching away substantially all the portions of the electrically insulating material disposed on the layer of conductive etch resistant material and on the side surfaces of the at least some of the metallic conductors.

In another aspect, the present invention provides a wafer level chip scale package comprising:

a semiconductor die having a plurality of pads on a surface;

metallic conductors coupled to and extending a first predetermined distance from the plurality of pads;

an etch resistant layer on free ends of the metallic conductors;

a layer of insulation on the surface, the layer of insulation having an exposed surface a second predetermined distance from the surface, wherein the second predetermined distance is less than the first predetermined distance; and

reflowable material adhering to the etch resistant layer and to at least portions of side surfaces of substantially all of the metallic conductors.

### BRIEF DESCRIPTION OF THE DRAWINGS

An embodiment of the present invention will now be fully described, by way of example, with reference to the drawings of which:

FIG. 1 shows a flowchart detailing a process for forming a WL-CSP in accordance with the prior art;

FIGS. 2A-E shows cross-sectional views of the WL-CSP being formed in accordance with the process in FIG. 1;

FIG. 3 shows a flowchart detailing a process for forming a WL-CSP in accordance with the present invention;

FIGS. 4A-E shows cross-sectional views of the WL-CSP being formed in accordance with the process in FIG. 3;

FIGS. 5-7 show enlarged cross-sectional views of a portion of the WL-CSP being formed in FIGS. 4C-E; and

FIG. 8 shows a cross-sectional view of the film placed on the semiconductor wafer as part of enhancing the process in FIG. 3.

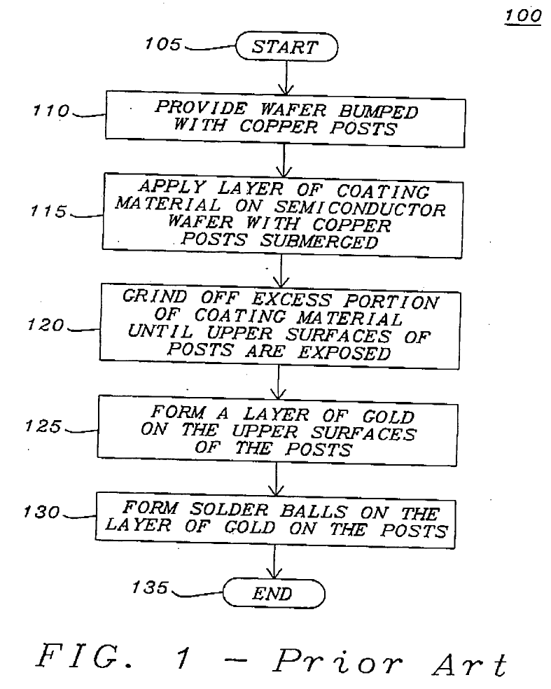

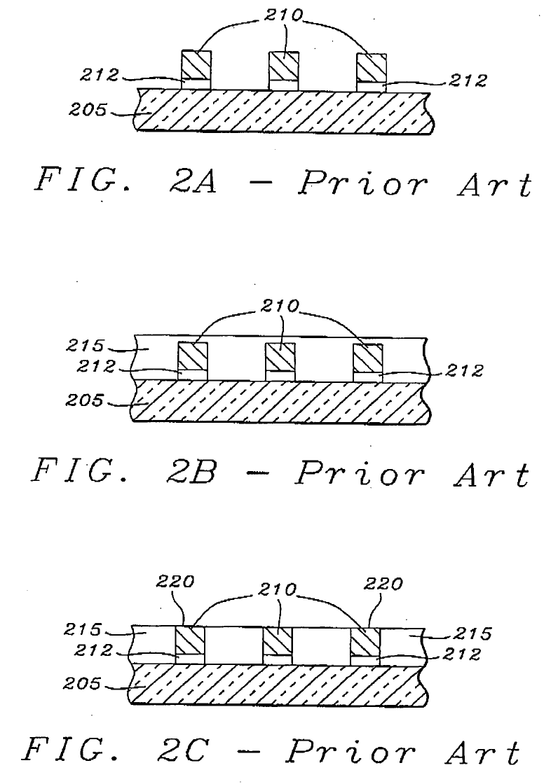

### DETAIL DESCRIPTION OF THE DRAWINGS

A layer of gold is disposed on upper surfaces of copper pillars on a wafer. Coating material is then applied on the water with an extrusion process to a lower level relative to the height of the copper pillars, leaving the copper pillars protruding above the upper surface of the coating material. Etchant is disposed to remove the portions of coating material on the layer of gold and the portions of coating material adhering to side surfaces of the protruding copper pillars. Solder deposits are then disposed on the layer of gold on the copper pillars, and the assembly is reflowed. The solder deposits form into balls on the layer of gold on the copper pillars, with the copper pillars protruding into the solder balls. Hence, the solder balls adhere to the layer of gold and in addition, the solder balls advantageously also adhere to the side surface of the copper pillars.

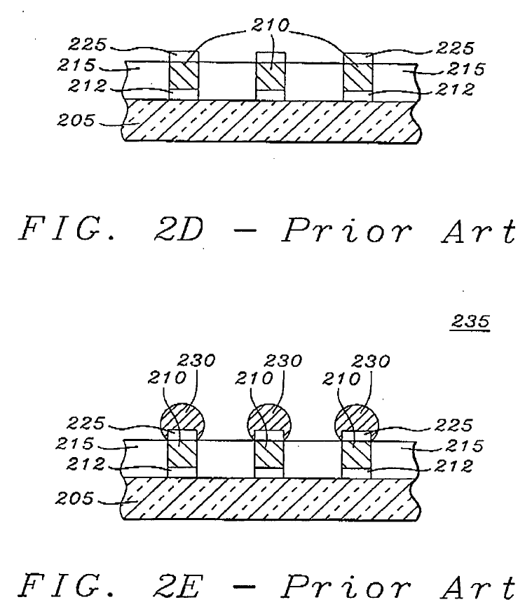

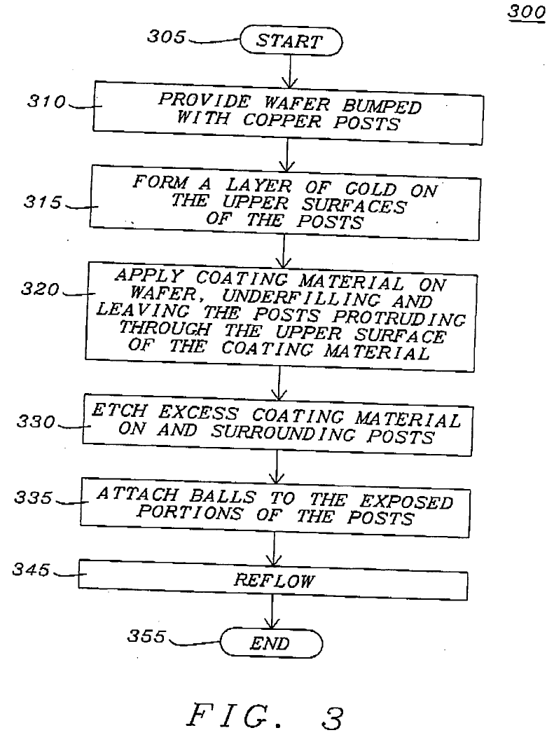

With reference to FIG. 3 and FIGS. 4A-E, a process 300 of forming a WL-CSP in accordance with the present invention, starts 305 with providing 310 a semiconductor wafer 205 with copper pillars 210 extending from die pads 212 on the semiconductor wafer 205, as shown in FIG. 4A. As mentioned earlier, U.S. patent application Ser. No. 09/564,382 by Francisca Tung, filed on Apr. 27, 2000, titled “Improved Pillar Connections For Semiconductor Chips and Method Of Manufacture”, and Continuation-In-Part U.S. patent application Serial No. (Not yet assigned.) by Francisca Tung, filed on Apr. 26, 2000 titled “Improved Pillar Connections For Semiconductor Chips and Method Of Manufacture”, and assigned to a common assignee as the present patent application, teaches forming at least some of such pillar structures as described herein. These patent applications are incorporated herein by reference.

A layer of gold 405 is then formed 315 on the upper surfaces 225 of the copper pillars 210, as shown in FIG. 4B. The layer of gold 405 is often referred to as gold flash, and can be formed using deposition, as will be known to one skilled in the art. The layer of gold provides a conductive etch resistant layer to prevent the copper pillars from being etched by etchant in a subsequent etching process.

Alternatively, a layer of nickel can be first formed on the upper surfaces 225 of the copper pillars 210, and a layer of gold formed on the layer of nickel. The layer of nickel forms a barrier to prevent diffusion of gold unto the copper, in the event the etching process removes portions of the layer of gold and/or diffusion of the gold into the copper pillars 210, leaves the copper pillars 210 exposed. When the layer of nickel is used, then the reference “405” in the drawings refers to the two layers of nickel and gold forming a conductive etch resistant layer.

Next, with reference to FIG. 4C, coating material is applied 320 in fluid form on the semiconductor wafer 205 to form a layer of coating 410 which has an upper surface which is lower relative to the height of the copper pillars 210. Consequently, the copper pillars 210 with the layer of gold 405 protrudes through the layer of coating material 410. Ideally, the layer of coating material 410 is lower by 20-30 μm. The layer of coating material 410 is formed using an extrusion process. This is accomplished with equipment such as MicroE from FAS Technologies of Dallas, Tex., USA. The coating material used is APS epoxy Wafer Coating Underfill (WCU), Dexter's underfill epoxy or any photo imageable coating material. With the MicroE extrusion coating equipment and the APS WCU epoxy, the equipment settings include POH rate 115 micro-liters (μl) per second, shuttle velocity 2.5 millimeter (mm), coating gap 125 μm, and extrusion head shim of 0.2 mm.

With the extrusion coating process 80-90% of the coating material that is dispensed forms the layer of coating 410, and a single dispense can produce the layer of coating 410 with the required thickness. In addition the extrusion coating process can dispense the coating material having a desired thickness to a tolerance of 2%. Extrusion coating is typically employed in the production of flat panel displays.

Hence, the present invention, as described, advantageously forms a layer of coating material on a semiconductor wafer more quickly and with less wastage than the spin coating process, and with the required thickness with a single application.

The layer of coating 410 can also be formed using known spin coating processes, however, the spin coating process must be controlled to produce the layer of coating 410 having a predetermined thickness. For example, the quantity of coating material that is disposed on the semiconductor wafer 205, the type of coating material used, and the speed and duration at which the semiconductor wafer 205 is spun, can be selected to produce the layer of coating material 410 having the desired thickness. An example is a Spin Coater machine by SITE of the USA, which applies a coating of BCB or polymide or epoxy based coating material. The setting for the spin coating machine includes first coating speed of 1500 revolutions per minute (rpm) for a period of 30 seconds; and second coating speed of 1800 rpm for 20 seconds, to coat 30-40 μm layer of coating material.

Another method forming the layer of coating 410 is using a molding process in conjunction with a Teflon® film, similar to that taught in U.S. Pat. No. 5,891,384 assigned to Apic Yamada Corporation of Japan, which is incorporated by reference.

After applying the layer of coating material 410, the semiconductor wafer is then heated to cure the layer of coating 410. The heat is applied at a temperature of 350° C. for 45 to 60 minutes in a nitrogen (N2) environment. Typically, an oven with a controlled nitrogen chamber is used for curing.

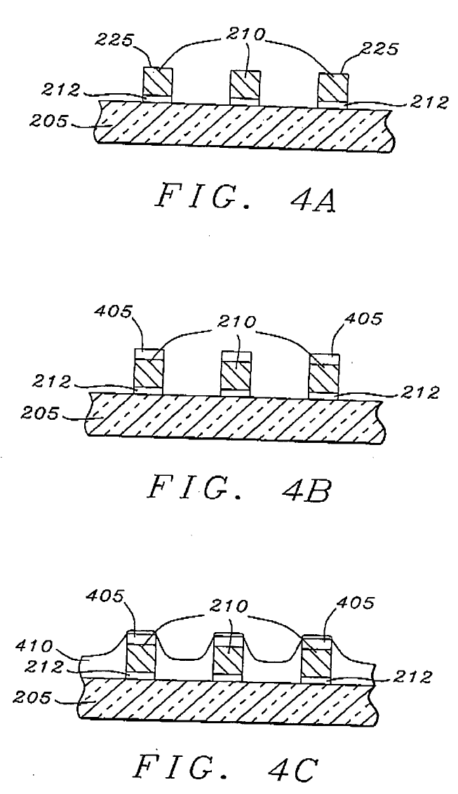

FIG. 5 shows an enlarged sectional view of one of the copper pillars 210 with the layer of gold 405 after the layer of coating 410 has been formed. Portions 505 of the cured layer of coating material 410 adhere to the upper surface 510 of the gold layer 405, and portions 515 of the cured coating material 410 adhere to side surfaces 520 of the copper pillars 210.

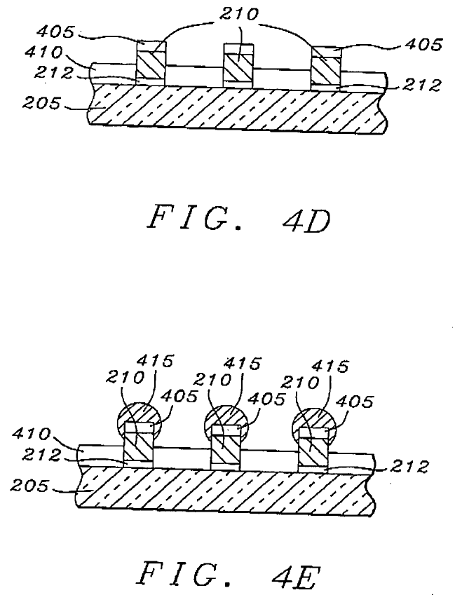

Subsequently, etchant is applied to the coated surface of the semiconductor wafer 205 to etch 330 away the portions 505 and 515 of the cured layer of coating material 410 on the gold layers 405 and on the side surfaces 505 of the copper pillars 210. FIG. 4D shows the semiconductor wafer 205 after etching, and FIG. 6 shows an enlarged side sectional view of one of the copper pillars 210 with the layer of gold, with the portions 505 and 515 of the cured layer of coating material 410 on the gold layers 405 and on the side surfaces 505 of the copper pillars 210, are etched away.

When plasma etching is employed the plasma etchant comprises a gas composition of 5% CF₄, 90% O₂, 5% Ar, with a power setting of 400 watts for a duration of 15 min minutes.

The present invention advantageously forms a layer of coating material having relatively smaller portions that need to be removed, thus allowing etching to be used and avoiding the need for mechanical grinding.

With reference to FIG. 4E, after etching 330, solder deposits are disposed on the copper pillars 210, and reflowed 345. The molten solder forms solder balls 415 attached 335 to the copper pillar 210. The process 300 then ends 355.

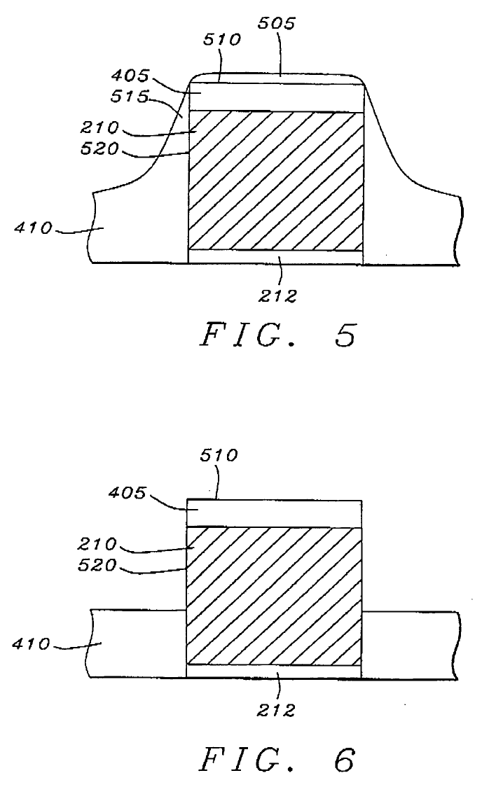

FIG. 7 shows an enlarged sectional view of one of the solder balls 415 attached to the copper pillars 210 after reflow. The copper pillar 210 with the layer of gold 405 protrudes into the solder ball 415, and the solder adheres to the surface 510 of the layer of gold 405. In addition, the solder ball 415 adheres to the side surfaces 520 of the copper pillar 210.

The present invention, as described, advantageously allows solder to adhere to the layer of gold and the side surfaces of the copper pillar resulting in a stronger mechanical joint and a more reliable electrical connection.

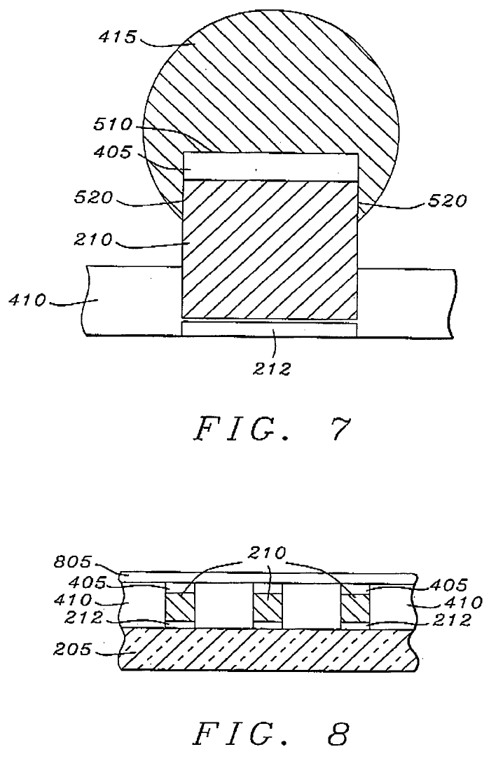

With reference to FIG. 8 an additional cleaning step can be used prior to etching 330 to enhance the efficiency of the etching process. After the applying 320 the coating material 410 on the semiconductor wafer 205, but prior to curing the coating material 410, Teflon® film 805 is placed over the semiconductor wafer 210, and pressure applied to force the Teflon® film against the semiconductor wafer 210. The Teflon® film 805 is then removed, taking with it the uncured portions 505 of the coating material. Subsequently, this leaves less of the cured portions 505 and 515 of the coating material that need to be removed by the etching process 330.

Teflon® film is also known as release film which is more commonly used in molding. When the layer of coating is formed by a molding process in conjunction with release film, the release film prevents the mold compound from getting on the surface 510 of the layer of gold 405 and also on the side surfaces 520 of the copper pillar 210, during the molding process.

Examples of release film that can be used to aid cleaning uncured portions of coating material is release film by 3M of the USA. The release film can be applied manually.

Alternatively, laser cleaning can be employed to clean away the uncured portions of coating material on the layer of gold 405. Laser cleaning is known to one skilled in the art, and an example of laser cleaning equipment that may be utilized is that manufactured by Advanced Systems Automation Limited (ASA) of Singapore.

Hence, the present invention, as described, produces a WL-CSP without subjecting the semiconductor wafer to mechanical grinding. In addition, the joint between the solder balls and the copper pillars are more reliable.

This is accomplished by forming an etch resistant conductive layer on pillar bumps on a semiconductor wafer, disposing a layer of coating material on the wafer with the bumps extending through and protruding from the surface of the layer of coating material. Subsequently, portions of the coating material on the top and the sides of the bumps are etched away, and solder balls attached to the exposed portion of the bumps.

Therefore, the present invention provides a method for forming a wafer level chip scale package and package formed thereby, which overcomes or at least reduces the abovementioned problems of the prior art.

It will be appreciated that although only one particular embodiment of the invention has been described in detail, various modifications and improvements can be made by a person skilled in the art without departing from the scope of the present invention.

1. A method for forming a wafer level chip scale semiconductor package, the method comprising the steps of:
a) providing a semiconductor wafer having a surface with a plurality of pads, wherein each of the pads has a metallic conductor extending a first predetermined distance away from the surface;
b) forming a layer of conductive etch resistant material on free ends of the metallic conductors;
c) disposing electrically insulating material on the surface of the semiconductor wafer, wherein the layer of electrically insulating material has an exposed surface a second predetermined distance from the surface of the semiconductor wafer, wherein the second predetermined distance is less than the first predetermined distance, and wherein portions of the electrically insulating material are disposed on the layer of conductive etch resistant material and on side surfaces of at least some of the metallic conductors;
d) etching away substantially all the portions of the electrically insulating material disposed on the layer of conductive etch resistant material and on the side surfaces of the at least some of the metallic conductors.

2. A method in accordance with claim 1 further comprising the steps of:
e) disposing reflowable material on the conductive etch resistant layer on the free ends of the metallic conductors; and
f) reflowing the semiconductor wafer causing the reflowable material to adhere to the conductive etch resistant layer and at least some of the side surfaces of the metallic conductors.

3. A method in accordance with claim 1 wherein step (b) comprises the step of depositing conductive etch resistant material on the free ends of the metallic conductors.

4. A method in accordance with claim 3 wherein step (b) comprises the step of depositing gold.

5. A method in accordance with claim 3 wherein step (b) comprises the step of depositing a layer of nickel, and subsequently depositing a layer of gold on the layer of nickel.

6. A method in accordance with claim 1 wherein step (b) comprises the step of plating etch resistant material on the free ends of the metallic conductors.

7. A method in accordance with claim 1 wherein step (c) comprises the step of dispensing the electrically insulating material with an extrusion coating process.

8. A method in accordance with claim 1 wherein step (c) comprises a single dispensing step.

9. A method in accordance with claim 1 wherein step (c) comprises the step of spin coating the layer of electrically insulating material on the surface of the semiconductor wafer.

10. A method in accordance with claim 9 wherein step (c) comprises the step of spin coating one of the coating materials from the group including underfill coating materials and photo imageable materials.

11. A method in accordance with claim 1 wherein step (c) comprises the step of molding the layer of electrically insulating material on the surface of the semiconductor wafer using release film.

12. A method in accordance with claim 1 wherein step (d) comprises the step of plasma etching.

13. A method in accordance with claim 1 wherein step (e) comprises the step of printing deposits of solder.

14. A method in accordance with claim 1 further comprising, after step (c) and before step (d), the step of curing the electrically insulating material.

15. A method in accordance with claim 14, after step (c) and before the step of curing the electrically insulating material, the step of cleaning the portions of the electrically insulating material disposed on the layer of conductive etch resistant material.

16. A method in accordance with claim 15 wherein the step of cleaning comprises the step of:
applying release film on the layer of conductive etch resistant material; and
removing the release film.

17. A method in accordance with claim 15 wherein the step of cleaning comprises the step of laser cleaning.

18. A wafer level chip scale package comprising:
a semiconductor die having a plurality of pads on a surface;
metallic conductors coupled to and extending a first predetermined distance from the plurality of pads;
an etch resistant layer on free ends of the metallic conductors;
a layer of insulation on the surfaces the layer of insulation having an exposed surface a second predetermined distance from the surface, wherein the second predetermined distance is less than the first predetermined distance; and
reflowable material adhering to the etch resistant layer and to at least portions of side surfaces of substantially all of the metallic conductors.

19. A wafer level chip scale package in accordance with claim 18 wherein the metallic conductors comprise copper conductors.

20. A wafer level chip scale package in accordance with claim 19 wherein the copper conductors comprise a plurality of plated copper layers.

21. A wafer level chip scale package in accordance with claim 18 wherein the etch resistant layer comprises a layer of gold.

22. A wafer level chip scale package in accordance with claim 18 wherein the etch resistant layer comprises a layer of nickel with a layer of gold thereon.

23. A wafer level chip scale package in accordance with claim 22 wherein the thickness of the layer of gold is less than the difference between the first predetermined distance and the second predetermined distance.

24. A wafer level chip scale package in accordance with claim 18 wherein the layer of insulation comprises a material selected from the group including mold compound, encapsulant epoxy, underfill coating, and photo imageable material, such as benzocyclobutene (BCB) or polymide.

25. A wafer level clip scale package in accordance with claim 18 wherein the reflowable material comprises solder.

26. A wafer level chip scale package in accordance with claim 25 wherein the solder comprises eutectic solder.
